(19) United States
(12) Patent Application Publication
(10) Pub. No.: US 2004/0262762 A1
(43) Pub. Date: Dec. 30, 2004

(54) Method of providing via in a multilayer semiconductor device

(76) Inventors: Ming-Shuoh Liang, Kaohsiung (TW); Tze-Liang Lee, Hsinchu (TW); Shih-Chang Chen, Hsin-Chu (TW)

Correspondence Address: DUANE MORRIS, LLP, IP DEPARTMENT, ONE LIBERTY PLACE, PHILADELPHIA, PA, 19103-7396, US

(21) Appl. No.: 10/603,261

(22) Filed: Jun. 25, 2003

(51) Int. Cl. H01L 23/48

(52) U.S. Cl. 257/758

(57) ABSTRACT

A border and inner via design for a pad which aids reducing stress and eliminative crack penetration into a die is presented. It is emphasized that this abstract is provided to comply with the rules requiring an abstract which will allow a searcher or other reader to quickly ascertain the subject matter of the technical disclosure. It is submitted with the understanding that it will not be used to interpret or limit the scope or meaning of the claims.

### FIELD OF INVENTION

The present invention relates to a providing via in a multilayer semiconductor device. In several embodiments, the present invention's method of providing via in a multilayer semiconductor device may act to reduce die sawing chipping.

### BACKGROUND OF THE INVENTION

Semiconductor devices are typically fabricated on large semiconductor wafers in multiple passes. Over a fabrication time period, the semiconductor device (also referred to as a die) will be fabricated with multiple layers. Once the fabrication process is complete, the individual circuits must be separated from each other. A typical process for this separation is called scribing.

Referring now to FIG. 1, as will be familiar to those of ordinary skill in the semiconductor fabrication arts, a danger in the separation process is that cracks and other imperfections can develop during the separation process, often as a result of scribing. Pads 10, which are connection points to provide electrical connectivity with the die 2, are often a point where such failures manifest.

As a partial solution, scribe streets 1 are used which separate adjacent die 2 and are typically arranged in a uniform pattern over the entire wafer. Horizontal and vertical scribe streets 1 are not always identical in width. Scribe streets 1 may vary from around 3 mils to around 7 mils, depending on the process used.

Pads 10 are typically located on an outside edge of a die 2 and will be located adjacent to the scribe street 1. Many current pad designs of test keys on scribe lines for copper/low-resistence (Cu/low-K) designs enlarge a chipping area when sawing the die on the wafer. Chipping often occurs along a die edge, resulting in poor reliability or even complete damage to the circuitry on the die.

### BRIEF DESCRIPTION OF THE DRAWINGS

FIG. 1 is an exemplary schematic view of a die and scribe streets;

FIG. 2a and FIG. 2b are schematic illustrations of square and octagonal pad designs of the prior art;

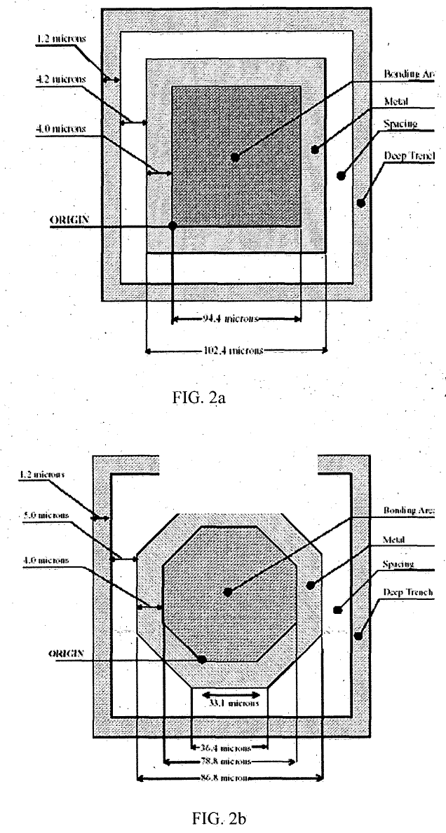

FIGS. 3a is a top planar view, and 3b is a partial view in cross-section of a first embodiment of a pad design of present invention;

FIGS. 4a is a top planar view, and 4b is a partial view in cross-section of a second embodiment of a pad design of present invention;

FIGS. 5a is a top planar view, and 5b is a partial view in cross-section of a third embodiment of a pad design of present invention; and

FIGS. 6a is a top planar view, and 6b is a partial view in cross-section of a fourth embodiment of a pad design of present invention.

### DETAILED DESCRIPTION OF THE PREFERRED EMBODIMENT

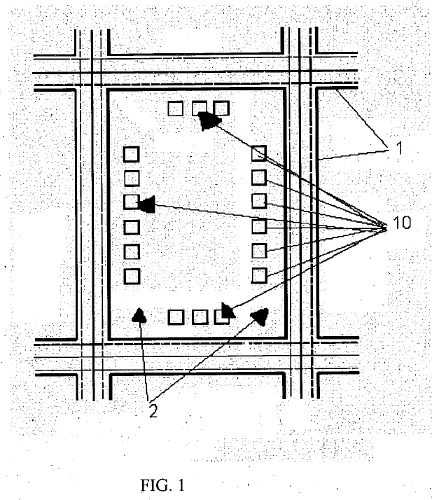

In embodiments of the present invention, pad 10 (e.g., FIG. 1) comprises a border and inner via design. These embodiments may aid in reducing stress and eliminating crack penetration into a die (e.g., die 2 in FIG. 1).

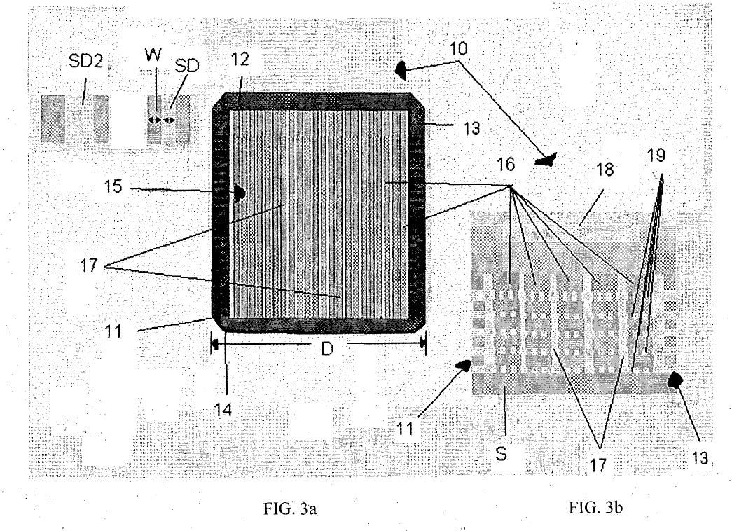

Referring now to FIG. 3a and FIG. 3b, in a first embodiment, via 16 for multilayer semiconductor device 2 (FIG. 1) are created by providing a first via set on a first layer of semiconductor device 2, e.g. on substrate S. A substantially rectilinear first peripheral border 11,12,13,14 is provided, e.g. fabricated, on first layer S of semiconductor device 2. The interior of first peripheral border 11,12,13,14 defines inner area 15. In a currently envisioned process, the substantially rectilinear first peripheral border 11,12,13,14 defines a rectangle, a square, an octagon, or the like. Further, in a currently preferred embodiment maximum distance in a single plane of two opposing sides of the substantially rectilinear first peripheral border, e.g. distance D in FIG. 3a between border 11 and border 13, is approximately 70 μm.

A plurality of first via 16 are provided on first layer S within inner area 15 as part of the first via set. As illustrated in FIG. 3a, the plurality of first via 16 may be arranged in substantially parallel lines having predetermined width W and predetermined separation distance SD between some or each of first via 16 to adjacent first via 16.

As a next layer is fabricated for semiconductor device 2 (FIG. 1), a subsequent via set, e.g. a second via set, is provided on the next layer of semiconductor device 2. It will be understood that subsequent layers will be disposed above a prior layer, e.g. that, as used herein for exemplary purposes, the second layer will be disposed above the first layer. The second via set may be substantially identical to the first via set and will be disposed substantially parallel to the first via set in a plane defined by the second layer, e.g. the second via set will comprise via 16 that are disposed substantially parallel to and substantially above first via 16 of the first via set. As the second via set is provided, conductive pathway 19 between each of the first via 16 of the first via set and each of the corresponding first via 16 of the second via set is further provided.

As illustrated in FIG. 3b, this process may be continued for each subsequent layer of semiconductor device 2 (FIG. 1), resulting in layers of mirrored via 16. As will be understood by those of ordinary skill in the semiconductor fabrication arts, a final layer may be provided which adds conductive pad 18, e.g. a metal or other conductive area to an accessible layer of semiconductor device 2.

In a first embodiment, substantially rectilinear first peripheral border 11,12,13,14 defines a rectangle, e.g. a square. The plurality of first via 16 comprise slots 17 between via 16 at predetermined separation distances SD. Slots 17 may aid in reducing pad stiffness. First via 16 need not be of uniform widths. In an exemplary embodiment, each side 11,12,13,14 is approximately 5 μm wide. In this embodiment, predetermined width W is approximately 1.5 μm; predetermined separation distance SD between adjacent first via 16 is approximately 1.0 μm; and outermost via 16, e.g. via 16a and via 16b, are separated from their adjacent border, 11 and 13, by approximately 1 μm.

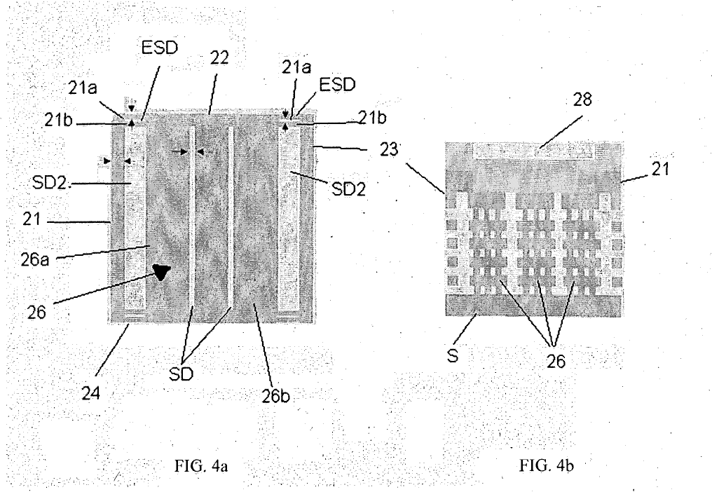

Referring now to FIG. 4a and FIG. 4b, in an alternative embodiment, substantially rectilinear first peripheral border 21,22,23,24 defines an rectangle, e.g. a square, where each side 21,22,23,24 is approximately 5 μm wide. However, as opposed to the types and characteristics of the embodiment illustrated in FIG. 3a and FIG. 3b, two sides, 21 and 23, are substantially uniform. Each of the other two sides 22 and 24 comprises outer edge and inner edge, e.g. outer edge 21a and inner edge 21b, separated by separation distance ESD. Separation distance ESD may acts to release stress.

In an exemplary embodiment, outer edge 21a and inner edge 21b are each approximately 2 μm wide and ESD is approximately 0.5 μm. Further, in the exemplary embodiment, predetermined width W is approximately 12 μm, leading to wider and fewer first via 26. However, first via 16 need not be of uniform widths. In the exemplary embodiment, separation distance SD between these first via 26 to an adjacent first via 26 is approximately 2.0 μm. Each first via 26 is substantially parallel and adjacent to side 21 and 23. First via 26a and 26b are separated from sides 21 and 23, respectively, by approximately 10 μm.

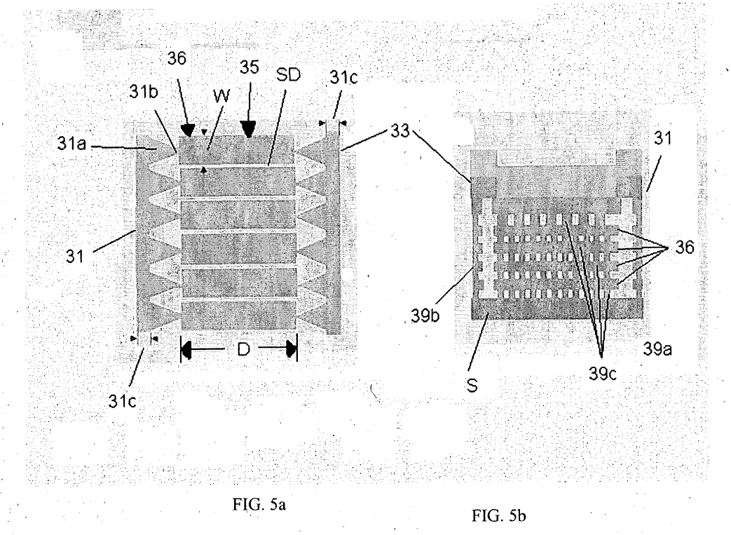

Referring now to FIG. 5a and FIG. 5b, in a further embodiment, a first via set is provided, e.g. fabricated, on a first layer of semiconductor device 2 (FIG. 1) by providing first peripheral border 31 on a first layer of semiconductor device 2, e.g. substrate S. The first via set further comprises second peripheral border 33 provided on the first layer where second peripheral border 33 is disposed substantially parallel to first peripheral border 31 at predetermined distance D. First peripheral border 31 and second peripheral border 33 define inner area 35. A plurality of first via 36 are provided on the first layer of semiconductor device 2 within inner area 35 where first via 36 may be arranged in substantially parallel lines having predetermined width W and predetermined separation distance SD to an adjacent first via 36. Further, first via 36 are disposed substantially perpendicular to first peripheral border 31 and second peripheral border 33.

Subsequent layers of semiconductor device 2 (FIG. 1) may possess subsequent via sets, e.g. a second via set will be provided on a second layer of a semiconductor device where the subsequent layer is disposed above the previous layer. For example, the second layer may be disposed on top of the first layer. These subsequent via sets may be provided by providing a via set substantially identical to the prior via set, e.g. the first via set, and disposed substantially parallel to the prior, e.g. first, via set in a plane defined by the second layer. Conductive pathway 39a will be provided between first peripheral border 31 of a prior via set and first peripheral border 31 of subsequent via set. Conductive pathway 39b will likewise be provided between the second peripheral border 33 of the prior via set and second peripheral border 33 of the subsequent via set. Additionally, conductive pathway 39c will be provided between each of first via 36 of the prior via set and each of first via 36 of the subsequent via set which will be disposed substantially parallel to and substantially above first via 36 of the first via set.

In this embodiment, first peripheral border 31 and second peripheral border 33 may further comprise a repeating inner design, e.g. a substantially sawtooth pattern as illustrated in FIG. 5a. Preferably, apex 31b of each tooth 31a of the sawtooth pattern will be conductively connected to a nearest first via 36.

In currently envisioned embodiments, typical dimensions for first peripheral border 31 and second peripheral border 33 are each approximately 10 μm wide. Inner area 35 is typically approximately 40 μm wide. Predetermined width W is typically approximately 12 μm.

In one embodiment, the repeating inner design further comprises outer rectilinear portion 31c and an inner pattern of teeth 31a arranged in a substantially sawtooth pattern wherein conductive pathway 39a of first peripheral border 31 is disposed proximate outer rectilinear portion 31c of first peripheral border 31 and conductive pathway 39b of second peripheral border 33 is disposed proximate outer rectilinear portion 33c of second peripheral border 33. In this embodiment, typical values for distance D, from an outer edge of a border 31,33 perpendicularly to a nearest apex, e.g. 31b, is approximately 10 μm and a width of outer rectilinear portion 31c,33c is approximately 4 μm.

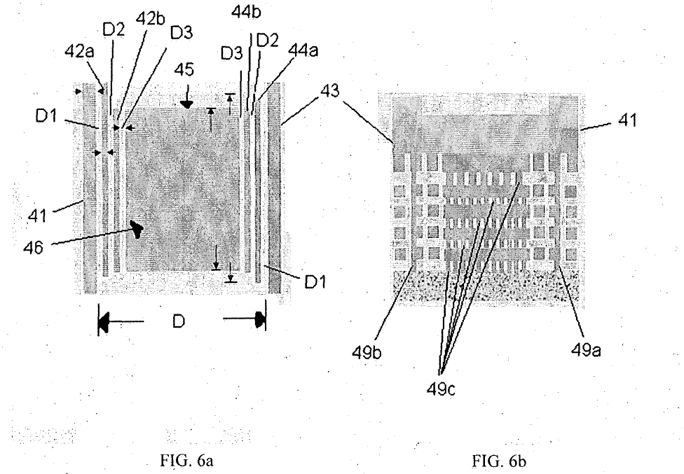

Referring now to FIG. 6a and FIG. 6b, in a further embodiment, a plurality of bordering elements are provided to aid in blocking a crack in semiconductor device 2 (FIG. 1), should one be created during the separation process. In this embodiment, a first via set is provided, e.g. fabricated, on a first layer of semiconductor device 2 by providing first peripheral border 41 and second peripheral border 43 on the first layer of a semiconductor device, where second peripheral border 43 is disposed substantially parallel to first peripheral border 41. Second peripheral border 43 is further disposed at distance D where inner area 45 is defined by the area in between first peripheral border 41 and second peripheral border 43.

Additional sets of inner borders are provided in inner area 45. First inner border 42a is disposed in inner area 45 substantially parallel to first peripheral border 41 at separation distance D₁ and second inner border 44a disposed in inner area 45 substantially parallel to second peripheral border 43 at separation distance D₁. Further, third inner border 42b is disposed in inner area 45 substantially parallel to first inner border 42a at separation distance D₂ and fourth inner border 44b disposed in inner area 45 substantially parallel to second inner border 42a at separation distance D₂. First via 46 are provided on the first layer of semiconductor device 2 (FIG. 1) within inner area 45 in between third inner border 42b and fourth inner border 44b at separation distance D₃ from third inner border 42b and fourth inner border 44b.

For subsequent layers, subsequent via sets are provided, e.g. a second via set is provided on a second layer of semiconductor device 2 (FIG. 1). These subsequent via sets, e.g. the second via set, are disposed on the subsequent layers above the prior layer, e.g. the second via set is disposed above the first via set. For these subsequent via sets, a subsequent via set is provided to be substantially identical to the prior via set with the subsequent via set disposed substantially parallel to the prior via set in a plane defined by the prior layer. Conductive pathway 49a will be provided between first inner border 42a of the prior via set and first inner border 42a of the subsequent via set. Conductive pathway 49b will likewise be provided between third inner border 44a of the prior via set and third inner border 44a of the subsequent via set. Additionally, conductive pathway 49c will be provided between first via 46 of the prior via set and first via 46 of the subsequent second via set.

In an embodiment, for each via set first peripheral border 41 and second peripheral border 43 are each approximately 5 μm wide; distance D₁ from an outer edge of first peripheral border 41 perpendicularly to a furthest distance on an outer edge of second peripheral border 43 is approximately 70 μm; first inner border 42a and second inner border 44a are each approximately 2 μm wide; third inner border 42b and fourth inner border 44b are each approximately 2 μm wide; first inner border 42a is separated from each of first peripheral border 41 and third inner border 42b by approximately 2 μm; third inner border 42b is separated from each of second peripheral border 43 and fourth inner border 44b by approximately 2 μm; third inner border 42b and fourth inner border 44b are separated from the inner area by approximately 2 μm; and inner area 45 comprises a rectangle approximately 30 μm wide and 60 μm long.

In an embodiment, first peripheral border 41 is longer than first inner border 42a, first inner border 42a is longer than third inner border 42b, second peripheral border 43b is longer than second inner border 44a, and second inner border 44a is longer than fourth inner border 44b. In this embodiment, first peripheral border 41 may be substantially the same length as second peripheral border 43, first inner border 42a may be substantially the same length as second inner border 44a , and third inner border 42b may be substantially the same length as fourth inner border 44b.

In all these embodiments, the order of creation of the via set constituent parts is not critical and the above descriptions should not be read to imply a precise order for creating constituent parts for a via set. Further, the dimensions for the various embodiments given above are for exemplary embodiments and are not limitations of the invention as a whole.

It will be understood that various changes in the details, materials, and arrangements of the parts which have been described and illustrated above in order to explain the nature of this invention may be made by those skilled in the art without departing from the principle and scope of the invention as recited in the appended claims.

We claim:

1. A method of providing via for a multilayer semiconductor device, comprising:
a. providing a first via set on a first layer of a semiconductor device, further comprising:
i. providing a substantially rectilinear first peripheral border on a first layer of a semiconductor device, an interior of the first peripheral border defining an inner area;
ii. providing a plurality of first via on the first layer of the semiconductor device within the inner area, the plurality of first via arranged in substantially parallel lines having a predetermined width, each of the plurality of first via having a predetermined separation distance to an adjacent first via; and
b. providing a second via set on a second layer of a semiconductor device, the second layer disposed above the first layer, the second layer further comprising:
i. providing the second via set to be substantially identical to the first via set, the second via set disposed substantially parallel to the first via set in a plane defined by the second layer; and
ii. providing a conductive pathway between a predetermined number of the first via of the first via set and those via of the second via set which are disposed substantially parallel to and substantially above the first via of the first via set.

2. The method of claim 1, wherein:
a. each substantially rectilinear first peripheral border is at least one of (i) a rectangle, (ii) a square, or (iii) an octagon; and
b. a maximum distance in a single plane of two opposing sides of the substantially rectilinear first peripheral border of a via set is approximately 70 μm.

3. The method of claim 1, wherein:
a. each side of the substantially rectilinear first peripheral border is approximately 5 μm wide;
b. the predetermined width is approximately 1.5 μm;
c. the predetermined separation distance to an adjacent first via is approximately 1.0 μm; and
d. each of the first via that is substantially parallel and adjacent to a side of the substantially rectilinear first peripheral border is separated from that side by approximately 1 μm.

4. The method of claim 1, wherein:
a. each side of the substantially rectilinear first peripheral border which is substantially parallel to the first via is approximately 5 μm wide;
b. each side of the substantially rectilinear first peripheral border which is substantially perpendicular to the first via comprises an outer edge and an inner edge, each approximately 2 μm wide, the outer edge and the inner edge separated by a separation distance of approximately 0.5 μm;
c. the predetermined width is approximately 12 μm;
d. the predetermined separation distance to an adjacent first via is approximately 2.0 μm; and
e. each via substantially parallel and adjacent to a side of the substantially rectilinear first peripheral border is separated from that side by approximately 10 μm.

5. A multilayer semiconductor device, comprising:
a. a first via set on a first layer of a semiconductor device, further comprising:
i. a substantially rectilinear first peripheral border on a first layer of a semiconductor device, an interior of the first peripheral border defining an inner area;
ii. a plurality of first via on the first layer of a semiconductor device within the inner area, the plurality of first via arranged in substantially parallel lines having a predetermined width, each of the plurality of first via having a predetermined separation distance to an adjacent first via; and
b. a second via set on a second layer of a semiconductor device, the second layer disposed above the first layer, the second via set further comprising:
i. a second via set substantially identical to the first via set, the second via set disposed substantially parallel to the first via set in a plane defined by the second layer; and
ii. a conductive pathway between each of the first via of the first via set and each of the first via of the second via set disposed substantially parallel to and substantially above the first via of the first via set; and
c. a pad disposed at a surface of the semiconductor device; and
d. a conductive pathway operatively in communication with at least one of the first via of the first via set and the pad.

6. A multilayer semiconductor device of claim 5, wherein:
a. each substantially rectilinear first peripheral border is at least one of (i) a rectangle, (ii) a square, or (iii) an octagon; and
b. a maximum distance in a single plane of two opposing sides of the substantially rectilinear first peripheral border of a via set is approximately 70 μm.

7. A multilayer semiconductor device of claim 5, wherein:
a. each side of the substantially rectilinear first peripheral border which is substantially parallel to the first via is approximately 5 μm wide;
b. each side of the substantially rectilinear first peripheral border which is substantially perpendicular to the first via comprises an outer edge and an inner edge each approximately 2 μm wide, the outer edge and the inner edge separated by a separation distance of approximately 0.5 μm;
c. the predetermined width is approximately 12 μm;
d. the predetermined separation distance to an adjacent first via is approximately 2.0 μm; and
e. each via substantially parallel and adjacent to a side of the substantially rectilinear first peripheral border is separated from that side by approximately 10 μm.

8. A method of providing via for a multilayer semiconductor device, comprising:
a. providing a first via set on a first layer of a semiconductor device, further comprising:
i. providing a first peripheral border on a first layer of a semiconductor device;
ii. providing a second peripheral border on the first layer, the second peripheral border disposed substantially parallel to the first peripheral border at a predetermined distance, the first peripheral border and the second peripheral border defining an inner area in between the first peripheral border and the second peripheral border; and
iii. providing a plurality of first via on the first layer of a semiconductor device within the inner area, the first via arranged in substantially parallel lines having a predetermined width and a predetermined separation distance to an adjacent first via, the first via disposed substantially perpendicular to the first peripheral border and the second peripheral border; and
b. providing a second via set on a second layer of a semiconductor device, the second layer disposed above the first layer, further comprising:
i. providing a second via set substantially identical to the first via set, the second via set disposed substantially parallel to the first via set in a plane defined by the second layer;
ii. providing a conductive pathway between the first peripheral border of the first via set and the first peripheral border of the second via set;
iii. providing a conductive pathway between the second peripheral border of the first via set and the second peripheral border of the second via set; and
iv. providing a conductive pathway between each of the first via of the first via set and each of the first via of the second via set disposed substantially parallel to and substantially above the first via of the first via set.

9. The method of claim 8, further comprising:
a. providing at least one of the first peripheral border or the second peripheral border with a repeating inner design.

10. The method of claim 9, wherein:
a. the repeating inner design comprises a substantially sawtooth pattern.

11. The method of claim 10, wherein:
a. an apex of each tooth of the sawtooth pattern is conductively connected to a nearest co-planar via.

12. The method of claim 9, wherein the repeating inner design further comprises:
a. an outer rectilinear portion; and
b. an inner substantially sawtooth pattern;
c. wherein the conductive pathway of the first peripheral border is disposed proximate the outer rectilinear portion of the first peripheral border and the conductive pathway of the second peripheral border is disposed proximate the outer rectilinear portion of the second peripheral border

13. The method of claim 9, wherein:
a. a distance from an outer edge of the outer rectilinear portion perpendicularly to an apex of a tooth of the sawtooth pattern is approximately 10 μm; and
b. a width of the outer rectilinear portion is approximately 4 μm.

14. The method of claim 8, wherein:
a. each the first peripheral border and the second peripheral border are each approximately 10 μm wide;
b. the inner area is approximately 40 μm wide;
c. the predetermined width is approximately 12 μm.

15. A multilayer semiconductor device, comprising:
a. a first via set on a first layer of a semiconductor device, further comprising:
i. a first peripheral border on a first layer of a semiconductor device;
ii. a second peripheral border on the first layer, the second peripheral border disposed substantially parallel to the first peripheral border at a predetermined distance, the first peripheral border and the second peripheral border defining an inner area in between the first peripheral border and the second peripheral border; and
iii. a plurality of first via on the first layer of a semiconductor device within the inner area, the first via arranged in substantially parallel lines having a predetermined width and a predetermined separation distance to an adjacent first via, the first via disposed substantially perpendicular to the first peripheral border and the second peripheral border; and
b. a second via set on a second layer of a semiconductor device, the second layer disposed above the first layer, further comprising:
i. a via set substantially identical to the first via set, the second via set disposed substantially parallel to the first via set in a plane defined by the second layer;
ii. a conductive pathway between the first peripheral border of the first via set and the first peripheral border of the second via set;
iii. a conductive pathway between the second peripheral border of the first via set and the second peripheral border of the second via set; and
iv. a conductive pathway between each of the first via of the first via set and each of the first via of the second via set disposed substantially parallel to and substantially above the first via of the first via set.

16. The multilayer semiconductor device of claim 15, wherein:
a. the first peripheral border and the second peripheral border further comprise a repeating inner design.

17. The multilayer semiconductor device of claim 16, wherein:
a. the repeating inner design comprises a substantially sawtooth pattern.

18. A method of providing via for a multilayer semiconductor device, comprising:
a. providing a first via set on a first layer of a semiconductor device, further comprising:
i. providing a first peripheral border on the first layer of a semiconductor device;
ii. providing a second peripheral border on the first layer of a semiconductor device, the second peripheral border disposed substantially parallel to the first peripheral border, the second peripheral border further disposed at a distance defining an inner area in between the first peripheral border and the second peripheral border;
iii. providing a first inner border disposed in the inner area substantially parallel to the first peripheral border at a predetermined separation distance;
iv. providing a second inner border disposed in the inner area substantially parallel to the second peripheral border at the predetermined separation distance;
v. providing a third inner border disposed in the inner area substantially parallel to the first inner border at a predetermined separation distance;
vi. providing a fourth inner border disposed in the inner area substantially parallel to the second inner border at the predetermined separation distance; and
vii. providing a first via on the first layer of a semiconductor device within the inner area in between the second inner border and the fourth inner border at a predetermined separation distance from the third inner border and the fourth inner border; and
b. providing a second via set on a second layer of a semiconductor device, the second layer disposed above the first layer, further comprising:
i. providing a second via set substantially identical to the first via set, the second via set disposed substantially parallel to the first via set in a plane defined by the second layer;
ii. providing a conductive pathway between the first inner border of the first via set and the first inner border of the second via set;
iii. providing a conductive pathway between the third inner border of the first via set and the third inner border of the second via set; and
iv. providing a conductive pathway between the first via of the first via set and the first via of the second via set.

19. The method of claim 18, wherein:
a. the first peripheral border and the second peripheral border are each approximately 5 μm wide;
b. a distance from an outer edge of the first peripheral border perpendicularly to a furthest distance on an outer edge of the second peripheral border is approximately 70 μm;
c. the first inner border and the second inner border are each approximately 2 μm wide;
d. the third inner border and the fourth inner border are each approximately 2 μm wide;
e. the first inner border is separated from each of the first peripheral border and the third inner border by approximately 2 μm;
f. the third inner border is separated from each of the second peripheral border and the fourth inner border by approximately 2 μm;
g. the third inner border and the fourth inner border are separated from the inner area by approximately 2 μm; and
h. the inner area is a rectangle approximately 30 μm wide and 60 μm long.

20. The method of claim 19, wherein:
a. the first peripheral border is longer than the first inner border;
b. the first inner border is longer than the third inner border;
c. the second peripheral border is longer than the second inner border; and
d. the second inner border is longer than the fourth inner border.

21. The method of claim 20, wherein:
a. the first peripheral border is substantially the same length as the second peripheral border;
b. the first inner border is substantially the same length as the second inner border; and
c. the third inner border is substantially the same length as the fourth inner border.

22. A multilayer semiconductor device, comprising:
a. a first via set on a first layer of a semiconductor device, further comprising:
i. a first peripheral border on the first layer of a semiconductor device;
ii. a second peripheral border on the first layer of a semiconductor device, the second peripheral border disposed substantially parallel to the first peripheral border, the second peripheral border further disposed at a distance defining an inner area;
iii. a first inner border disposed in the inner area substantially parallel to the first peripheral border at a predetermined separation distance;
iv. a second inner border disposed in the inner area substantially parallel to the second peripheral border at the predetermined separation distance;
v. a third inner border disposed in the inner area substantially parallel to the first inner border at a predetermined separation distance;
vi. a fourth inner border disposed in the inner area substantially parallel to the second inner border at the predetermined separation distance; and
vii. a first via on the first layer of a semiconductor device within the inner area in between the second inner border and the fourth inner border at a predetermined separation distance from the third inner border and the fourth inner border; and
b. a second via set on a second layer of a semiconductor device, the second layer disposed above the first layer, further comprising:
i. a via set substantially identical to the first via set, the second via set disposed substantially parallel to the first via set in a plane defined by the second layer;
ii. a conductive pathway between the first inner border of the first via set and the first inner border of the second via set;
iii. a conductive pathway between the third inner border of the first via set and the third inner border of the second via set; and
iv. a conductive pathway between the first via of the first via set and the first via of the second via set.

23. The multilayer semiconductor device of claim 22, wherein:
a. the first peripheral border and the second peripheral border are each approximately 5 μm wide;
b. a distance from an outer edge of the first peripheral border perpendicularly to a furthest distance on an outer edge of the second peripheral border is approximately 70 μm;
c. the first inner border and the second inner border are each approximately 2 μm wide;
d. the third inner border and the fourth inner border are each approximately 2 μm wide;
e. the first inner border is separated from each of the first peripheral border and the third inner border by approximately 2 μm;
f. the third inner border is separated from each of the second peripheral border and the fourth inner border by approximately 2 μm;
g. the third inner border and the fourth inner border are separated from the inner area by approximately 2 μm; and
h. the inner area is a rectangle approximately 30 μm wide and 60 μm long.

24. The semiconductor device of claim 22, wherein:
a. the first peripheral border is longer than the first inner border;
b. the first inner border is longer than the third inner border;
c. the second peripheral border is longer than the second inner border; and
d. the second inner border is longer than the fourth inner border.

25. The semiconductor device of claim 22, wherein:
a. the first peripheral border is substantially the same length as the second peripheral border;
b. the first inner border is substantially the same length as the second inner border; and
c. the third inner border is substantially the same length as the fourth inner border.
